(19) United States
(12) Patent Application Publication
(10) Pub. No.: US 2024/0345172 A1
(43) Pub. Date: Oct. 17, 2024

(54) BATTERY MODULE MONITORING AND REPURPOSING

(71) Applicant: Caterpillar Inc., Peoria, IL (US)

(72) Inventors: Alexander C. CROSMAN, III, Dunlap, IL (US); Jason Lee MILLER, Princeville, IL (US); Keith N. TROISI, Dunlap, IL (US)

(73) Assignee: Caterpillar Inc., Peoria, IL (US)

(21) Appl. No.: 18/298,841

(22) Filed: Apr. 11, 2023

(51) Int. Cl. G01R 31/392; G01R 31/36; G01R 31/371; H01M 10/42

(52) U.S. Cl. CPC G01R 31/392; G01R 31/3648; G01R 31/371; H01M 10/425; H01M 2010/4271; H01M 2010/4278

(57) ABSTRACT

In some implementations, a module controller may obtain one or more values of one or more parameters associated with one or more battery cells included in the battery module. The module controller may store the one or more values of the one or more parameters associated with the one or more battery cells. The module controller may provide, to a controller of a battery pack, an indication of the one or more values of the one or more parameters.

### TECHNICAL FIELD

The present disclosure relates generally to batteries and, for example, to battery module monitoring and repurposing.

### BACKGROUND

A machine may include one or more battery packs to provide power to components of the machine, such as lights, computer systems, and/or a motor, among other examples. A battery pack may be associated with a modular design that includes multiple battery modules. A battery module may include multiple battery cells. A demand placed on batteries may vary significantly from one type of application to another. In some examples, a battery may be repurposed to a second application after a capability of the battery can no longer meet the demand of a first application. For example, a battery may first be used in a high demand application, such as associated with an electric vehicle. As a battery ages, and an amount of charge that can be stored by the battery decreases and/or a state of health of the battery decreases, the battery may be repurposed into a less demanding application, such as an application associated with solar energy storage. A battery (e.g., a battery cell) may be repurposed one or more times during a life-cycle of the battery.

Battery cells may be tested to determine whether the battery cell can continue to be used in a current application or if the battery cell needs to be repurposed to a less demanding application. The testing may include breaking down a battery pack and/or a battery module to separate individual battery cells. Once removed from the battery pack and/or the battery module, the battery cells may be separately tested to assess the state of health of each battery cell. The battery cells may then be regrouped to form new battery packs and/or new battery modules for a next use or application (e.g., by manually sorting battery cells having a similar state of health to form the new battery packs and/or new battery modules). This process is time consuming and expensive because each individual battery cell needs to be tested. Additionally, the battery cells may be assembled using permanent terminal-to-busbar welds. Therefore, the welds must be broken and then rewelded after the battery cells are sorted into the new battery packs and/or new battery modules. The process of disassembling each battery cell, testing each battery cell separately, sorting battery cells having similar properties together, and reassembling new battery packs and/or new battery modules is a time consuming, expensive, and inefficient process for monitoring and/or repurposing batteries.

U.S. Patent Application No. 2012/20068175 (the '175 application) discloses a battery module for a battery system including at least two battery modules, where each battery module is provided with a module monitoring unit arranged to monitor at least one performance related parameter for each secondary cell in the battery module. Parameters relating to the performance for each battery module are stored in a memory on the respective module monitoring unit. The module monitoring unit may be provided with sensors for measuring the performance related parameter. The performance related parameter may be measured for each battery module and/or for each secondary cell. In response to received and/or calculated data, a battery monitoring unit may perform independent adjustment of at least one parameter for the battery module, such as the state-of-charge of each of the plurality of battery modules based on the performance related parameter.

However, the '175 application does not disclose techniques for identifying and/or providing a repurposing level for a battery module. For example, the '175 application does not disclose storing and/or providing information associated with the battery module to facilitate identifying battery cells and/or battery modules for repurposing and/or reuse. Additionally, the '175 application does not disclose obtaining or storing information, such as a battery cell chemistry type, to ensure that different battery modules and/or battery cells can be repurposed together in a new battery module and/or a new battery pack.

The battery pack and battery module(s) of the present disclosure solve one or more of the problems set forth above and/or other problems in the art.

### SUMMARY

A battery module may include one or more battery cells; and a module controller that includes one or more programmable memories, configured to: obtain one or more values of one or more parameters associated with the one or more battery cells; store, in the one or more programmable memories, the one or more values of the one or more parameters associated with the one or more battery cells; and indicate, to a diagnostic device, a repurposing level of the battery module by providing an indication of the one or more values of the one or more parameters.

A method performed by a device associated with a battery module that is included in a battery pack may include obtaining one or more values of one or more parameters associated with one or more battery cells included in the battery module; storing the one or more values of the one or more parameters associated with the one or more battery cells; and providing, to a controller of the battery pack, an indication of the one or more values of the one or more parameters.

A battery pack may include a plurality of battery modules associated with respective module controllers and respective memories, each battery module including a plurality of battery cells; and a battery pack controller, configured to: obtain, from a module controller of the respective module controllers, an indication of one or more module parameters associated with a battery module, of the plurality of battery modules, that is associated with the module controller; determine, based on the one or more module parameters, one or more values of one or more parameters associated with the battery module; and provide, to the module controller, an indication of the one or more values of the one or more parameters to cause the one or more values to be stored in a memory, of the respective memories, that is associated with the battery module.

### BRIEF DESCRIPTION OF THE DRAWINGS

FIG. 1 is a diagram of an example battery pack described herein.

FIG. 2 is a diagram of an example associated with battery module monitoring and repurposing described herein.

FIG. 3 is a diagram of an example associated with battery module monitoring and repurposing described herein.

FIG. 4 is a flowchart of an example process associated with battery module monitoring and repurposing.

### DETAILED DESCRIPTION

This disclosure relates to a battery pack and/or a battery module, and is applicable to any machine application that uses power provided by a battery. As used herein, “battery cell,” “battery,” and “cell” may be used interchangeably. For example, “machine” may refer to any machine that performs an operation associated with an industry, such as mining, construction, farming, transportation, or any other industry. For example, a machine may be an electric vehicle, a hybrid vehicle, a compactor machine, a paving machine, a cold planer, a grading machine, a backhoe loader, a wheel loader, a harvester, an excavator, a motor grader, a skid steer loader, a tractor, and/or a dozer, among other examples. Additionally, or alternatively, the battery pack and/or the battery module described herein may be used in an energy storage application, such as for solar energy storage and/or wind energy storage, among other examples.

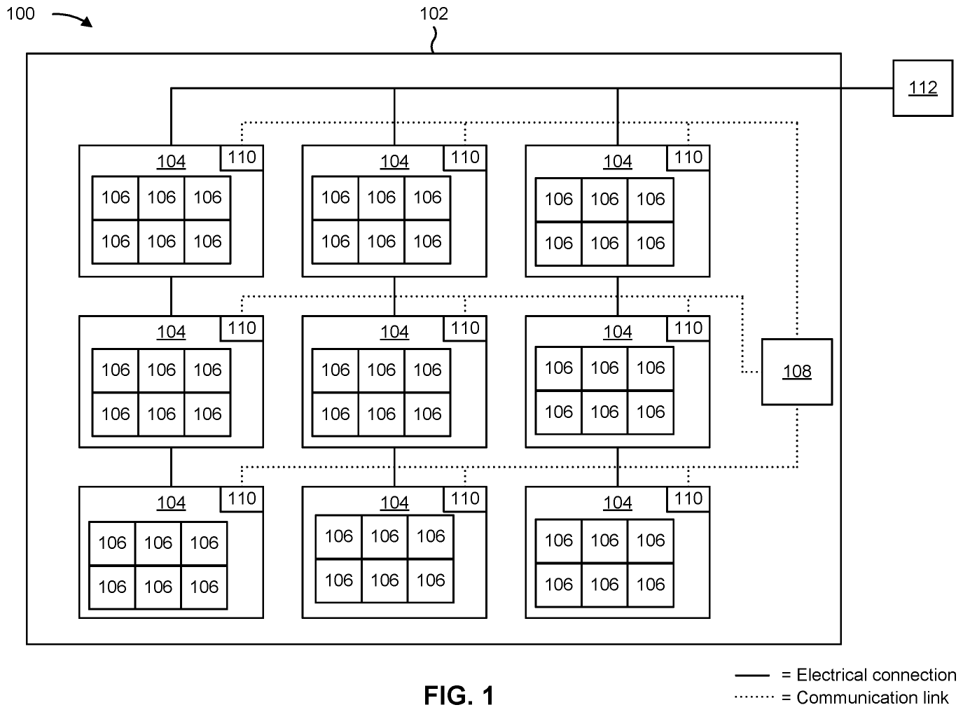

FIG. 1 is a diagram of an example battery pack 100 described herein. The battery pack 100 may include a battery pack housing 102, one or more battery modules 104, and one or more battery cells 106. The battery pack 100 includes a battery pack controller 108 associated with storing information and/or controlling one or more operations associated with the battery pack 100. Each battery module 104 includes a module controller 110 associated with storing information and/or controlling one or more operations associated with the battery module 104.

The battery pack 100 may be associated with a component 112. The component 112 may be powered by the battery pack 100. For example, the component 112 can be a load that consumes energy provided by the battery pack 100, such as a computing system or an electric motor, among other examples. As another example, the component 112 provides energy to the battery pack 100 (e.g., to be stored by the one or more battery cells 106). In such examples, the component 112 may be a power generator, a solar energy system, and/or a wind energy system, among other examples.

The battery pack housing 102 may include metal shielding (e.g., steel, aluminum, and/or the like) to protect elements (e.g., battery modules 104, battery cells 106, the battery pack controller 108, the module controllers 110, wires, circuit boards, cooling systems, and/or the like) positioned within battery pack housing 102. Each battery module 104 includes one or more battery cells 106 (e.g., positioned within a module housing of the battery module 104). The battery cells can be connected in series and/or in parallel within the battery module 104 (e.g., via terminal-to-busbar welds). Each battery cell 106 is associated with a chemistry type. The chemistry types may include lithium (Li-ion), nickel-metal hydride (NiMH), nickel cadmium (NiCd), lithium ion polymer (Li-ion polymer), lithium iron phosphate (LFP), and/or nickel manganese cobalt (NMC), among other examples.

The battery modules 104 can be arranged within the battery pack 100 in one or more strings. For example, the battery modules 104 are connected via electrical connections, as shown in FIG. 1. The electrical connections may be removable, such as via bolts and/or nuts at one or more terminals on housings of the battery modules 104. The battery modules 104 can be connected in series and/or in parallel. For example, a number of battery modules 104 may be connected in series to provide a particular voltage (e.g., to the component 112). Alternatively, a number of battery modules 104 may be connected in parallel to increase a current and/or a power output of the battery pack 100. The number of battery cells 106 included in each battery module 104, and the number of battery modules 104 included in the battery pack 100 (e.g., and the relative serial and/or parallel connections of the battery cells 106 and/or the battery modules 104) may be associated with the required output power and an intended use of the battery pack 100. For example, any number of battery cells 106 can be included in a battery module 104. Similarly, any number of battery modules 104 can be included in the battery pack 100.

The battery pack controller 108 is communicatively connected (e.g., via a communication link) to each module controller 110. The battery pack controller 108 may be associated with receiving, generating, storing, processing, providing, and/or routing information associated with the battery pack 100. The battery pack controller 108 may also be referred to as a battery pack management device or system. The battery pack controller 108 may communicate with the component 112 and/or a controller of the component 112, controls a start-up and/or shut-down procedure of the battery pack 100, monitors a string (e.g., of battery modules 104) current and/or voltage, and/or monitors and/or controls a current and/or voltage provided by the battery pack 100, among other examples. For example, the battery pack controller 108 may be associated with monitoring and/or determining a state-of-charge (SOC), a state of health (SOH), a depth of discharge (DOD), an output voltage, a temperature, and/or an internal resistance and impedance, among other examples, associated with a battery module 104 and/or associated with the battery pack 100.

The battery pack controller 108 includes a processor and/or memory. The processor may include a central processing unit, a graphics processing unit, a microprocessor, a controller, a microcontroller, a digital signal processor, a field-programmable gate array, an application-specific integrated circuit, and/or another type of processing component. The processor may be implemented in hardware, firmware, or a combination of hardware and software. In some implementations, the processor may include one or more processors capable of being programmed to perform one or more operations or processes described elsewhere herein. The memory may include volatile and/or nonvolatile memory. For example, the memory may include random access memory (RAM), read only memory (ROM), and/or another type of memory (e.g., a flash memory, a magnetic memory, and/or an optical memory). The memory may include internal memory (e.g., RAM, ROM, or a hard disk drive) and/or removable memory (e.g., removable via a universal serial bus connection). The memory may be a non-transitory computer-readable medium. The memory may store information, one or more instructions, and/or software (e.g., one or more software applications) related to the operation of the battery pack 100. The memory may include one or more memories that are coupled (e.g., communicatively coupled) to the processor, such as via a bus. Communicative coupling between a processor and a memory may enable the processor to read and/or process information stored in the memory and/or to store information in the memory.

A module controller 110 includes a cell monitoring board associated with reporting, to the battery pack controller 108, one or more parameters associated with battery cells 106 included in a given battery module 104. For example, the one or more parameters may include cell voltages, temperatures, chemistry types, a cell energy throughput, a cell internal resistance, and/or a quantity of charge-discharge cycles of the battery module, among other examples. The module controller 110 may include a processor (e.g., in a similar manner as described above in connection with the battery pack controller 108). In some implementations, the module controller 110 may not include a processor. For example, the module controller 110 may include one or more components configured to enable the module controller 110 to communicate with one or more sensors and to report values indicated by the one or more sensors to the module controller 110. A module controller 110 may include memory (e.g., in a similar manner as the memory described above in connection with the battery pack controller 108). For example, the module controller 110 may include programmable memory, such as an electrically erasable programmable read-only memory (EEPROM).

As indicated above, FIG. 1 is provided as an example. Other examples may differ from what is described with regard to FIG. 1.

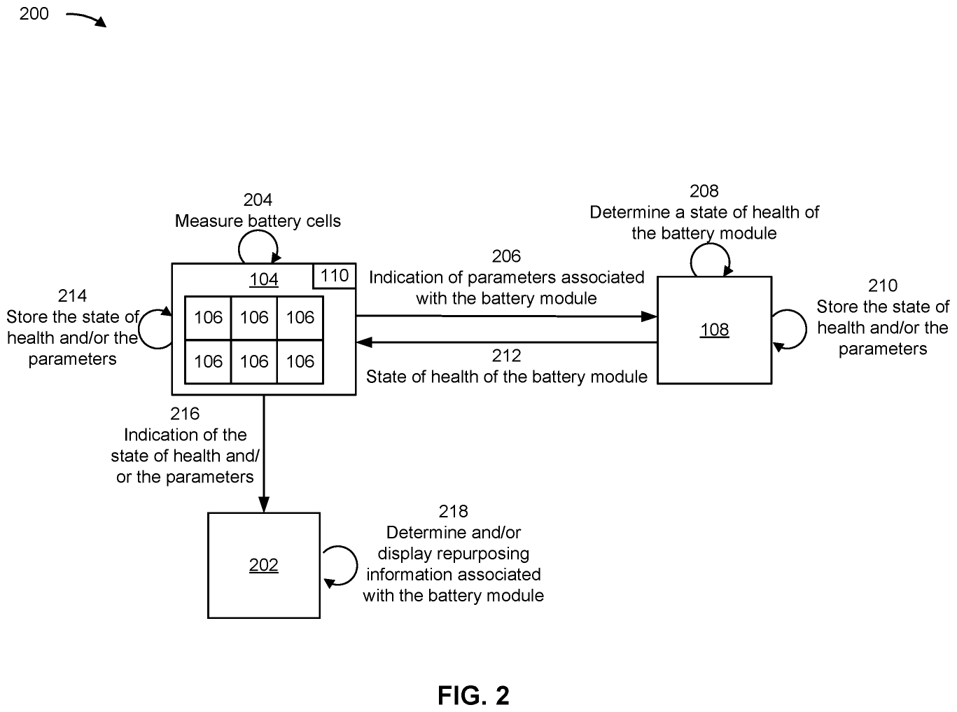

FIG. 2 is a diagram of an example 200 associated with battery module monitoring and repurposing described herein. As shown in FIG. 2, a battery module 104 (e.g., a module control 110 of the battery module 104) communicates with a diagnostic device 202. The diagnostic device 202 may be associated with identifying and/or determining repurposing information associated with the battery module 104, as described in more detail elsewhere herein.

The diagnostic device 202 includes one or more devices capable of receiving, generating, storing, processing, and/or providing information associated with repurposing and/or reusing the battery module 104. The diagnostic device 202 may include a communication device and/or a computing device. For example, the diagnostic device 202 may include a wireless communication device, a computer, a mobile phone, a laptop computer, a tablet computer, a desktop computer, or a similar type of device.

As shown by reference number 204, the battery module 104 (e.g., the module controller 110) measures one or more battery cells 106 included in the battery module 104. For example, the module controller 110 may obtain one or more values of one or more parameters associated with the one or more battery cells 106. The module controller 110 communicates with one or more sensors, such as a temperature sensor, a voltage sensor, and/or a current sensor, among other examples, to obtain measurements indicating the one or more values (e.g., measurement values) of the one or more parameters. For example, the one or more parameters may include a temperature, an energy throughput of the battery module, a cell voltage, a cell internal resistance, and/or a cell impedance, among other examples.

The module controller 110 obtains at least one of the one or more values from a memory (e.g., one or more programmable memories) of the battery module 104 and/or of the module controller 110. For example, the module controller 110 may store an indication of a quantity of charge-discharge cycles of the battery module 104 and/or of a given battery cell 106. A charge-discharge cycle may include charging a battery cell 106 (and/or all battery cells 106 included in the battery module 104) to a charge level that satisfies a charge threshold and discharging a charge of the battery cell 106 (and/or all battery cells 106 included in the battery module 104) to a charge level that satisfies a discharge threshold. The module controller 110 may store an indication of the quantity of charge-discharge cycles of the battery module 104 and/or of a given battery cell 106. As used herein, “satisfying” a threshold may, depending on the context, refer to a value being greater than the threshold, greater than or equal to the threshold, less than the threshold, less than or equal to the threshold, equal to the threshold, not equal to the threshold, or the like.

The module controller 110 obtains at least one of the one or more values from the battery pack controller 108. For example, as shown by reference number 206, the battery module 104 (e.g., the module controller 110) provides, and the battery pack controller 108 obtains, an indication of one or more parameters associated with the battery module 104. For example, the battery module 104 (e.g., the module controller 110) may provide, and the battery pack controller 108 may obtain, an indication of the one or more measurement values associated with the battery module 104 and/or one or more battery cells 106. For example, the module controller 110 may provide, and the battery pack controller 108 may obtain, an indication of an energy throughput of the battery module 104, a quantity of charge-discharge cycles of the battery module 104, a cell voltage of one or more battery cells 106 and/or of the battery module 104, a temperature of the battery module 104, and/or a change in a cell internal resistance of one or more battery cells 106 and/or of the battery module 104, among other examples.

The battery pack controller 108 determines one or more values for one or more parameters associated with the battery module 104 based on the one or more parameters associated with the battery module 104. For example, as shown by reference number 208, the battery pack controller 108 determines a state of health of the battery module 104. The state of health may be a measurement that indicates the level of degradation and remaining capacity of a battery. The battery pack controller 108 may determine a state of health for the battery module 104 based on information associated with all battery cells 106 included in the battery module 104. The state of health may indicate the difference between a battery at issue and a new battery (e.g., to indicate cell aging). For example, the state of health may be a ratio of the maximum battery charge to a rated capacity of the battery, expressed as a percentage. The state of health may be determined using a number of different parameters, such as internal resistance, internal impedance, internal conductance, capacity, voltage, self-discharge, ability to accept a charge, the quantity of charge-discharge cycles, an age, a temperature during previous use, and/or a total energy charged and/or discharged, among other examples.

As shown by reference number 210, the battery pack controller 108 stores (e.g., in memory of the battery pack controller 108) a value of the determined parameter(s) for the battery module 104. The battery pack controller 108 may store an indication of the one or more parameters associated with the battery module 104 (e.g., provided to the battery pack controller 108 by the module controller 110). For example, the battery pack controller 108 may store an indication of a value (e.g., a percentage value) of the state of health of the battery module 104. The battery pack controller 108 may obtain, determine, and/or store values of parameters associated with other battery modules 104 included in the battery pack 100 in a similar manner.

The battery pack controller 108 may identify repurposing categories associated with respective battery modules 104, of the battery modules 104 included in the battery pack 100, based on values, of the one or more parameters, associated with the respective battery modules 104. The battery pack controller may provide, to the module controller 110, an indication of the repurposing category associated with the battery module 104. For example, the battery pack controller 108 may group and/or categorize the battery modules 104 based on the value(s) of the parameter(s). For example, the battery pack controller 108 may categorize a battery module 104 in a category associated with a repurposing application type (e.g., high demand applications, medium demand applications, or low demand applications) based on the value(s) of the parameter(s), such as the state of health of the battery module 104. The module controller 110 may provide an indication of the repurposing category to the diagnostic device 202 to facilitate repurposing determinations, as described in more detail below.

As shown by reference number 212, the battery pack controller 108 provides, and the battery module 104 (e.g., the module controller 110) obtains, an indication of the value(s) of the parameter(s) determined by the battery pack controller 108. For example, the battery pack controller 108 may provide, and the battery module 104 (e.g., the module controller 110) may obtain, a value (e.g., a percentage value) of the state of health of the battery module 104. As shown by reference number 214, the battery module 104 (e.g., the module controller 110) may store an indication of the value of the state of health and/or values of other parameters associated with the battery module 104. For example, the module controller 110 may store (e.g., in a programmable memory associated with the module controller 110) an indicate of a value of the state of health, as an internal resistance, an internal impedance, an internal conductance, a capacity, a voltage, a self-discharge, an ability to accept a charge, a quantity of charge-discharge cycles, an age, a build date, an identifier (e.g., of the battery module 104), a temperature during previous use, a total energy charged and/or discharged, one or more battery misuse flags, and/or other parameters associated with the battery module 104. Additionally, the module controller 110 may store an indication of one or more module configuration parameters. The one or more module configuration parameters may include a chemistry type of the one or more battery cells, a cell connection type, and/or a temperature sensor placement, among other examples.

The one or more battery misuse flags may indicate that the battery module 104 and/or one or more battery cells 106 included in the battery module 104 have been misused and/or are no longer suitable for continued use. For example, the one or more battery misuse flags may indicate that the battery module 104 and/or one or more battery cells 106 have been damaged. As an example, if a battery cell 106 is discharged over or under a certain voltage, there are chemical changes within the battery cell 106 that increase the likelihood of damage (e.g., of a rapid increase of temperature during charging, which may be referred to as thermal runaway) if that battery cell 106 is recharged in the future. In such examples, a battery misuse flag may be stored in a programmable memory associated with the module controller 110 to indicate that the battery cell 106 and/or the battery module 104 is no longer suitable for repurposing and/or continued use.

The module controller 110 may measure, obtain, provide, and/or store the parameter(s) described herein periodically (e.g., every X minutes, hours, or days). As another example, the module controller 110 may measure, obtain, provide, and/or store the parameter(s) described herein based on detecting a trigger event. The trigger event may include obtaining an indication from the battery pack controller 108 (e.g., that triggers the module controller 110 to perform one or more of the operations described herein). The trigger event may include detecting a start-up or shut-down operation associated with the battery pack 100. The trigger event may include detecting that a measurement value (e.g., one or more of the measurement values described herein) satisfies a threshold.

The information stored by the module controller 110 enables repurposing and/or reuse determinations to be made efficiently for the battery module 104. For example, the battery cells 106 included in the battery module 104 may age similarly because the battery cells 106 may experience similar conditions during operation due to their close physical proximity within a configuration of the battery pack 100. Therefore, the parameter(s) of the battery module 104, such as the state of health, may be indicative of a repurposing level for the battery cells 106 included in the battery module 104. Further, the one or more module configuration parameters may enable a device (e.g., the module controller 110, the battery pack controller 108, and/or the diagnostic device 202) that is identifying battery modules 104 to be repurposed together into a new battery pack 100 to identify whether the configuration parameters of the battery modules 104 are compatible, as described in more detail elsewhere herein.

For example, the module controller 110 indicates, to the diagnostic device 202, a repurposing level of the battery module 104 by providing an indication of the one or more values of the one or more parameters. The repurposing level may be an indication of an applicability of the battery module 104 for one or more application types and/or a condition of the battery module 104 that is based on the one or more values of the one or more parameters associated with the one or more battery cells 106. For example, the repurposing level may include an indication of the state of health of the battery module 104. Additionally, the repurposing level may include, or be based on, one or more other parameters of the battery module 104 and/or battery cells 106 described herein.

For example, the module controller 110 may communicate with the diagnostic device 202 after the battery pack 100 has been disassembled. Therefore, information stored in a memory of the battery pack controller 108 may be unavailable at the time at which the diagnostic device 202 is performing an operation associated with repurposing the battery module 104 (e.g., because the battery pack 100 has been disassembled and the battery pack controller 108 may not be in the same physical location as the battery module 104). Storing the information described herein in a memory of the module controller 110 enables the operation associated with repurposing the battery module 104.

For example, as shown by reference number 216, the module controller 110 provides, and the diagnostic device 202 obtains, an indication of the state of health and/or one or more other parameters of the battery module 104 and/or of battery cells 106 included in the battery module 104. As shown by reference number 218, the diagnostic device 202 determines and/or displays repurposing information associated with the battery module 104. For example, the diagnostic device 202 may store an indication of the repurposing information. The repurposing information may include the state of health of the battery module 104, the one or more parameters associated with the battery module 104, and/or one or more module configuration parameters of the battery module 104.

The diagnostic device 202 may display the repurposing information for review by a user. For example, the diagnostic device 202 may store, in a database, an indication of repurposing information for multiple battery modules 104. The diagnostic device 202 may display information in the database for review by the user. This enables the user to quickly identify and/or sort battery modules 104 that can be used in the same application type and/or similar application types.

In some implementations, the diagnostic device 202 may identify battery modules 104 that can be used in the same application type and/or similar application types based on repurposing information associated with the battery modules 104. For example, the diagnostic device 202 may sort a value of a parameter, such as a state of health, associated with multiple battery modules 104 (e.g., that may have been originally assembled in different battery packs 100). The diagnostic device 202 may group and/or categorize the battery modules 104 based on the value(s) of the parameter(s). For example, the diagnostic device 202 may categorize a battery module 104 into a repurposing application type or group based on the value(s) of the parameter(s), such as the state of health of the battery module 104. The diagnostic device 202 may display the category and/or group associated with a battery module 104 to enable a user to quickly and easily identify a repurposing application for the battery module 104 without having to disassemble the battery module 104.

As indicated above, FIG. 2 is provided as an example. Other examples may differ from what is described with regard to FIG. 2.

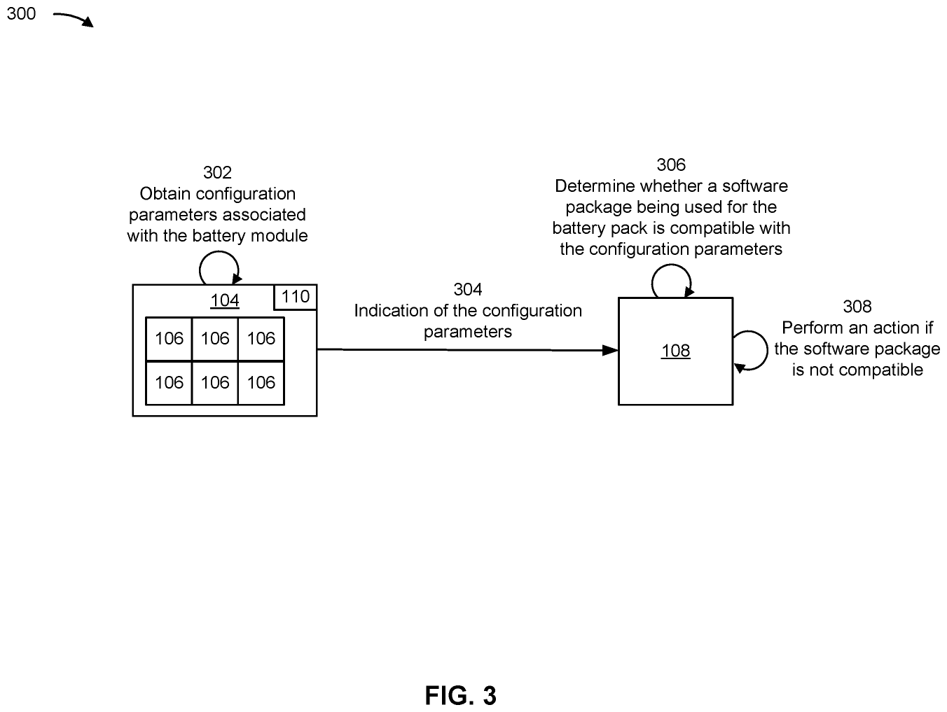

FIG. 3 is a diagram of an example 300 associated with battery module monitoring and repurposing described herein.

As shown by reference number 302, the battery module 104 (e.g., the module controller 110) obtains one or more module configuration parameters associated with a battery module 104. The one or more module configuration parameters may indicate a chemistry type of battery cells 106 included in the battery module 104 and/or assembly parameters of the battery module 104. The one or more module configuration parameters may include a chemistry type of the one or more battery cells 106, a cell connection type, and/or a sensor placement (e.g., a temperature sensor placement), among other examples. The module controller 110 may obtain or retrieve the one or more module configuration parameters from the memory associated with the module controller 110.

As shown by reference number 304, the battery module 104 (e.g., the module controller 110) provides, and the battery pack controller 108 obtains, an indication of the one or more module configuration parameters. The module controller 110 may provide the indication of the one or more module configuration parameters periodically (e.g., every X minutes, hours, or days). As another example, the module controller 110 may provide the indication of the one or more module configuration parameters based on detecting a trigger event. The trigger event may include obtaining an indication from the battery pack controller 108 (e.g., that triggers the module controller 110 to provide the indication of the one or more module configuration parameters). The trigger event may include detecting a start-up or shut-down operation associated with the battery pack 100.

The battery pack controller 108 may obtain one or more module configuration parameters from all battery modules 104 included in the battery pack 100. The battery pack controller 108 may perform one or more actions based on the one or more module configuration parameters obtained by the battery pack controller 108. The battery pack controller 108 may store (e.g., in the memory of the battery pack controller 108) an indication of the obtained module configuration parameters.

As an example, and as shown by reference number 306, the battery pack controller 108 determines whether a software package being executed by the battery pack controller 108 for controlling operations of the battery pack 100 is compatible with the one or more module configuration parameters of the battery module 104. For example, different battery chemistry types have significantly different cell characteristics and/or protection limits for safe operation. The software package may be associated with controlling a charging rate, a discharge rate, a voltage, and/or a current, among other examples, associated with a battery module 104 and/or battery cells 106 included in the battery pack 100.

The battery pack controller 108 determines whether the software package being executed by the battery pack controller 108 provides parameters of operation that meet protection limits for safe operation of the battery module 104. For example, the battery pack controller 108 may store one or more threshold values (e.g., for one or more operations associated with the battery pack 100, such as a charging rate, a discharge rate, a voltage, and/or a current, among other examples) for different module configuration parameters. The battery pack controller 108 may obtain one or more thresholds associated with the one or more configuration parameters indicated by the modular controller 110. The battery pack controller 108 may determine whether a value of an operation associated with the software package satisfies the one or more thresholds associated with the one or more configuration parameters indicated by the modular controller 110. For example, the battery pack controller 108 may determine whether a charging rate associated with the software package satisfies a charging rate threshold associated with the one or more configuration parameters (e.g., associated with a chemistry type of the battery cells 106 included in the battery module 104). If the value of an operation associated with the software package satisfies the one or more thresholds, then the battery pack controller 108 may determine that the software package is compatible with the one or more configuration parameters indicated by the modular controller 110. However, if the value of an operation associated with the software package does not satisfy the one or more thresholds, then the battery pack controller 108 may determine that the software package is not compatible with the one or more configuration parameters indicated by the modular controller 110. The battery pack controller 108 may determine whether the software package is compatible with all battery modules 104 included in the battery pack 100 in a similar manner.

As shown by reference number 308, the battery pack controller 108 performs an action if the software package is not compatible with at least one battery module 104 included in the battery pack 100. The action may include causing an operation of the battery pack to stop, based on determining that the software package is not compatible with the one or more module configuration parameters. The action may include switching the software package to a different software package, based on determining that the software package is not compatible with the one or more module configuration parameters. For example, the battery pack controller 108 may store a library that includes a set of software packages. The battery pack controller 108 may select a software package that is compatible with all battery modules 104 included in the battery pack 100 (e.g., based on the module configuration parameters indicated by the battery modules 104). As another example, the action may include providing, to another device or a display device of the battery pack 100, an indication, for display, that the software package is not compatible, based on determining that the software package is not compatible with the one or more module configuration parameters. The battery pack controller 108 may use the module configuration parameters for repurposing and/or reuse determinations. For example, the battery pack controller 108 may categorize (e.g., into repurposing categories) battery modules 104 that can be safely grouped together (e.g., in a battery pack 100) in a repurposed application.

As indicated above, FIG. 3 is provided as an example. Other examples may differ from what is described with regard to FIG. 3.

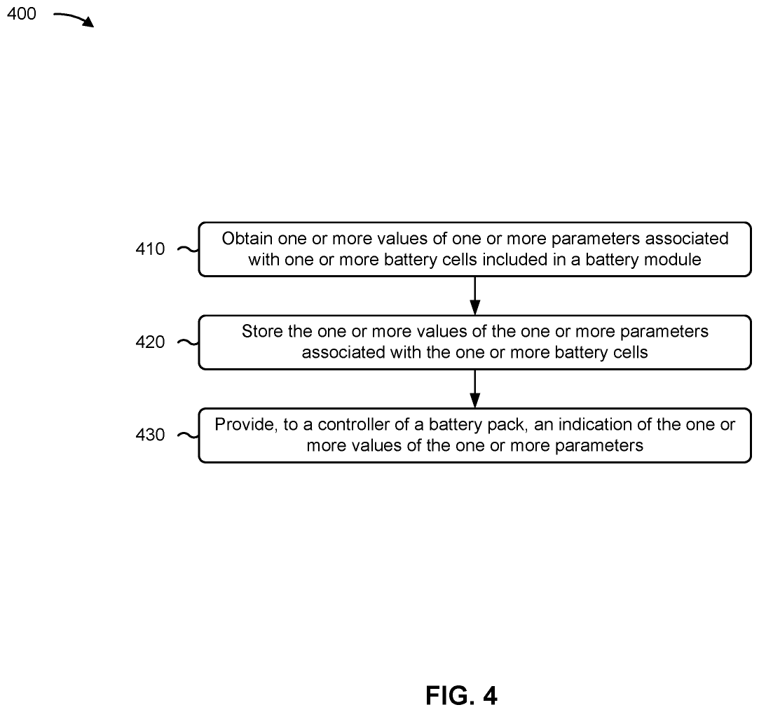

FIG. 4 is a flowchart of an example process 400 associated with battery module monitoring and repurposing. One or more process blocks of FIG. 4 may be performed by a module controller (e.g., module controller 110). Additionally, or alternatively, one or more process blocks of FIG. 4 may be performed by another device or a group of devices separate from or including the module controller, such as another device or component that is internal or external to the battery pack 100.

As shown in FIG. 4, process 400 may include obtaining one or more values of one or more parameters associated with one or more battery cells included in the battery module (block 410). For example, the module controller may obtain one or more values of one or more parameters associated with one or more battery cells included in the battery module, as described above. Obtaining the one or more values of the one or more parameters may include measuring one or more properties of the one or more battery cells to obtain the one or more values of the one or more parameters. Obtaining the one or more values of the one or more parameters may include obtaining, from the controller of the battery pack (e.g., the battery pack controller 108), information associated with at least one of the one or more parameters.

As further shown in FIG. 4, process 400 may include storing the one or more values of the one or more parameters associated with the one or more battery cells (block 420). For example, the module controller may store the one or more values of the one or more parameters associated with the one or more battery cells, as described above.

As further shown in FIG. 4, process 400 may include providing, to a controller of the battery pack, an indication of the one or more values of the one or more parameters (block 430). For example, the module controller may provide, to a controller of the battery pack, an indication of the one or more values of the one or more parameters, as described above.

The one or more parameters may include one or more module configuration parameters. The one or more module configuration parameters include at least one of a chemistry type of the one or more battery cells, a cell connection type, or a temperature sensor placement. The one or more parameters may include at least one of a state of health of the battery module, a cell voltage, or a temperature.

Process 400 may include providing, to a diagnostic device, an indication of the one or more values of the one or more parameters to indicate a repurposing level of the battery module.

Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

### INDUSTRIAL APPLICABILITY

Battery cells 106 may be tested to determine whether the battery cells 106 can continue to be used in a current application or if the battery cells 106 need to be repurposed to a less demanding application. The testing includes breaking down a battery pack 100 and/or a battery module 104 to separate individual battery cells 106. Once removed from the battery pack 100 and/or the battery module 104, the battery cells 106 may be separately tested to assess the state of health of each battery cell 106. The battery cells 106 may then be regrouped to form new battery packs 100 and/or new battery modules 104 for a next use or application (e.g., by manually sorting battery cells 106 having a similar state of health to the new battery packs 100 and/or new battery modules 104). This process is time consuming and expensive because each individual battery cell 106 needs to be tested. Additionally, welds of each battery cell 106 must be broken and then rewelded after sorting into the new battery packs and/or new battery modules. The process of disassembling each battery cell, testing each battery cell separately, sorting battery cells having similar properties together, and reassembling new battery packs and/or new battery modules is a time consuming, expensive, and inefficient process for monitoring and/or repurposing battery cells 106.

Some implementations described herein enable a battery module controller with self-monitoring diagnostics for determining battery modules 104 for repurposing and reusing and/or battery modules 104 associated with different chemistry types. For example, a module controller 110 of a battery module 104 may detect battery chemistry types of battery cells 106 within the battery module 104 as well as other parameters, such as the state of health of the battery module 104, that can be used for repurposing and reusing of the battery module 104. For example, the module controller 110 of a battery module 104 may store an indication of module configuration parameters and other parameters, such as the state of health of the battery module 104, that can be used for repurposing and reusing of the battery module 104. The module controller 110 may indicate a repurposing level or repurposing information of the battery module 104 (e.g., to a battery pack controller 108 and/or a diagnostic device 202) by providing an indication of the module configuration parameters and other parameters, such as the state of health of the battery module 104.

As a result, a repurposing application of the battery module 104 can be easily identified without disassembling the battery module 104 and/or without having access to the memory of the battery pack controller 108. For example, the repurposing level or repurposing information of the battery module 104 may indicate appropriate application types for which the battery module 104 can be repurposed or reused. This reduces time, effort, and/or complexity associated with identifying an appropriate application type and/or compatible battery modules 104 for repurposing the battery cells 106 included in the battery module 104. Additionally, the determination of the software package compatibility by the battery pack controller 108 reduces a likelihood that incompatible battery modules 104 are combined into a battery pack 100, thereby reducing a likelihood of poor operation of the battery pack 100 (e.g., that includes repurposed battery modules 104) and/or a failure of the battery pack 100.

What is claimed is:

1. A battery module, comprising:
one or more battery cells; and
a module controller that includes one or more programmable memories, configured to:
obtain one or more values of one or more parameters associated with the one or more battery cells;
store, in the one or more programmable memories, the one or more values of the one or more parameters associated with the one or more battery cells; and
indicate, to a diagnostic device, a repurposing level of the battery module by providing an indication of the one or more values of the one or more parameters.

2. The battery module of claim 1, wherein the battery module is included in a battery pack that includes a plurality of battery modules, and
wherein the module controller is further configured to:
provide, to a battery pack controller of the battery pack, an indication of the one or more values of the one or more parameters associated with the one or more battery cells.

3. The battery module of claim 1, wherein the one or more parameters include a state of health parameter of the battery module.

4. The battery module of claim 1, wherein the repurposing level indicates a condition of the battery module based on the one or more values of the one or more parameters associated with the one or more battery cells.

5. The battery module of claim 1, wherein the battery module is included in a battery pack that includes a plurality of battery modules, and
wherein the module controller, to obtain the one or more values of the one or more parameters, is configured to:
obtain one or more measurement values of the one or more battery cells;
provide, to a battery pack controller of the battery pack, an indication of the one or more measurement values; and
obtain, from the battery pack controller, an indication of the one or more values of the one or more parameters based on providing the indication of the one or more measurement values.

6. The battery module of claim 5, wherein the one or more measurement values are associated with at least one of:
an energy throughput of the battery module,
a quantity of charge-discharge cycles of the battery module,
a cell voltage,
a temperature of the battery module, or
a change in a cell internal resistance; and
wherein the one or more parameters include a state of health parameter of the battery module.

7. The battery module of claim 1, wherein the one or more parameters include at least one of:
a state of health,
an energy throughput,
a quantity of charge-discharge cycles,
a cell voltage,
a temperature,
a change in a cell internal resistance,
a cell chemistry type,
one or more battery misuse flags, or
a battery module configuration type.

8. A method performed by a device associated with a battery module that is included in a battery pack, comprising:
obtaining one or more values of one or more parameters associated with one or more battery cells included in the battery module;
storing the one or more values of the one or more parameters associated with the one or more battery cells, the one or more parameters including at least one of one or more module configuration parameters, or one or more measurement parameters of the one or more battery cells; and
providing, to a controller of the battery pack, an indication of the one or more values of the one or more parameters.

9. The method of claim 8, wherein obtaining the one or more values of the one or more parameters comprises:
measuring one or more properties of the one or more battery cells to obtain the one or more values of the one or more parameters.

10. The method of claim 8, wherein obtaining the one or more values of the one or more parameters comprises:
obtaining, from the controller of the battery pack, information associated with at least one of the one or more parameters.

11. The method of claim 8, further comprising:
providing, to a diagnostic device, an indication of the one or more values of the one or more parameters to indicate a repurposing level of the battery module.

12. The method of claim 8, wherein the one or more parameters include a repurposing level indicates a condition of the battery module based on the one or more values of the one or more parameters associated with the one or more battery cells.

13. The method of claim 8, wherein the one or more module configuration parameters include at least one of:
a chemistry type of the one or more battery cells,
a cell connection type, or
a temperature sensor placement.

14. The method of claim 8, wherein the one or more measurement parameters include at least one of:
a state of health of the battery module,
a cell voltage, or
a temperature.

15. A battery pack, comprising:
a plurality of battery modules associated with respective module controllers and respective memories, each battery module including a plurality of battery cells; and
a battery pack controller, configured to:
obtain, from a module controller of the respective module controllers, an indication of one or more module parameters associated with a battery module, of the plurality of battery modules, that is associated with the module controller;
determine, based on the one or more module parameters, one or more values of one or more parameters associated with the battery module; and
provide, to the module controller, an indication of the one or more values of the one or more parameters to cause the one or more values to be stored in a memory, of the respective memories, that is associated with the battery module.

16. The battery pack of claim 15, wherein the one or more module parameters include one or more module configuration parameters associated with the battery module, and
wherein the battery pack controller is further configured to:
determine whether a software package being executed by the battery pack controller for controlling operations of the battery pack is compatible with the one or more module configuration parameters; and
perform an action based on determining whether the software package is compatible with the one or more module configuration parameters.

17. The battery pack of claim 16, wherein the one or more module configuration parameters include a cell chemistry type of battery cells included in the battery module.

18. The battery pack of claim 16, wherein the action includes at least one of:
causing an operation of the battery pack to stop based on determining that the software package is not compatible with the one or more module configuration parameters,
switching the software package to a different software package based on determining that the software package is not compatible with the one or more module configuration parameters, or
providing, to another device or a display device of the battery pack, an indication, for display, that the software package is not compatible based on determining that the software package is not compatible with the one or more module configuration parameters.

19. The battery pack of claim 15, wherein the battery pack controller is further configured to:
identify repurposing categories associated with respective battery modules, of the plurality of battery modules, based on values, of the one or more parameters, associated with the respective battery modules; and
provide, to the respective module controllers, an indication of the repurposing categories.

20. The battery pack of claim 15, wherein the one or more parameters include a state of health parameter associated with the battery module.
